(19) United States
(12) Patent Application Publication
(10) Pub. No.: US 2012/0319923 A1
(43) Pub. Date: Dec. 20, 2012

(54) HOUSING OF ELECTRONIC DEVICE AND METHOD

(75) Inventors: ZHAO-YI WU, Shenzhen City (CN); YONG YAN, Shenzhen City (CN); YONG-FA FAN, Shenzhen City (CN); XUE-LI ZHANG, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/271,359

(22) Filed: Oct. 12, 2011

(30) Foreign Application Priority Data
Jun. 17, 2011 (CN) 201120204401.0

(51) Int. Cl. H01Q 1/40; C23C 14/06; C23C 14/35

(52) U.S. Cl. 343/873; 204/192.15

(57) ABSTRACT

In the present disclosure, a housing for electronic device and method for making the housing is disclosed. The housing includes a base, an antenna radiator, and a decoration layer. The antenna is formed on the base by injection molding and is covered by the decoration layer. The antenna radiator includes a primary layer and a plating layer. The antenna is covered and protected by the decoration layer, thus, the housing can be used for a long period.

### CROSS-REFERENCE TO RELATED APPLICATIONS

This application is related to co-pending U.S. patent applications (Attorney Docket No. US38297 No. US38298), entitled “HOUSING OF ELECTRONIC DEVICE AND METHOD”. Such applications have the same assignee as the present application. The above-identified applications are incorporated herein by reference.

### BACKGROUND

1. Technical Field

The present disclosure relates to housings of electronic devices, especially to a housing having an antenna formed thereon and a method for making the housing.

2. Description of Related Art

Electronic devices, such as mobile phones, personal digital assistants (PDAs) and laptop computers are widely used. Most of these electronic devices have antenna modules for receiving and sending wireless signals. A typical antenna radiator includes a thin metal radiator element mounted to a support member, and attached to a housing. However, the radiator element is usually exposed from the housing, and may be easily damaged and has a limited receiving effect. In addition, the radiator element and the support member occupy precious space.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary housing and the method for making the housing. Moreover, in the drawings like reference numerals designate corresponding parts throughout the several views. Wherever possible, the same reference numbers are used throughout the drawings to refer to the same or like elements of an embodiment.

FIG. 1 is a schematic view of an exemplary embodiment of a housing applied in an electronic device.

FIG. 2 is a cross-sectional view of a portion of the housing including antenna radiator taken along line II-II of FIG. 1.

FIG. 3 is a cross-sectional view of a portion of a molding machine of making the housing of FIG. 1.

FIG. 4 is similar to FIG. 3, but showing a base formed in a molding chamber.

FIG. 5 is similar to FIG. 4, but showing an antenna radiator formed on the base.

FIG. 6 is a schematic view of a PVD machine used in the present process.

### DETAILED DESCRIPTION

The disclosure is illustrated by way of example and not by way of limitation in the accompanying drawings. It should be noted that references to “an” or “one” embodiment in this disclosure are not necessarily to the same embodiment, and such references can include the meaning of “at least one” embodiment where the context permits.

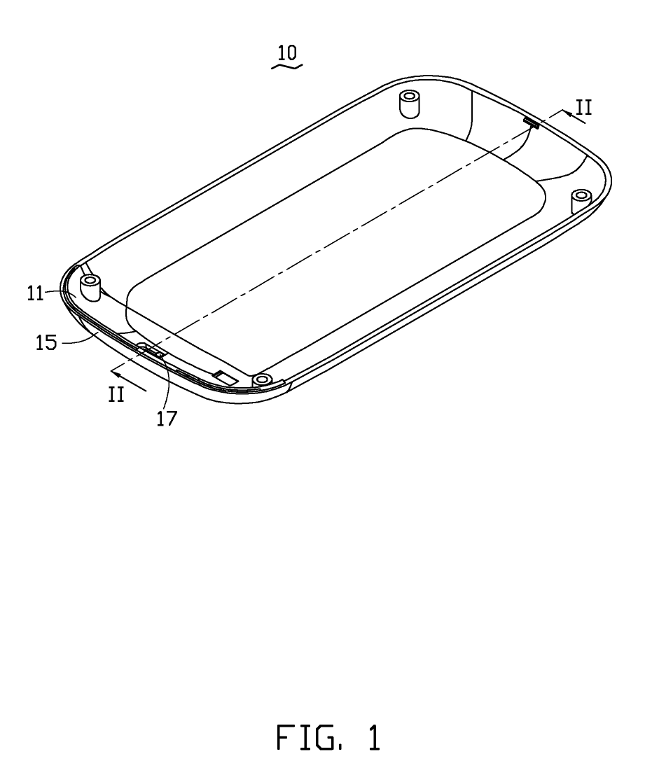

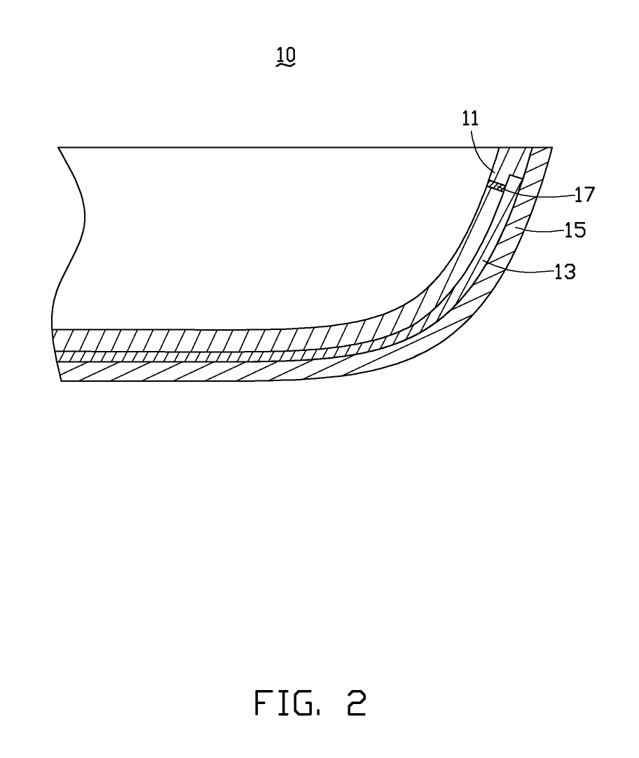

FIG. 1 shows an exemplary embodiment of a housing 10 for an electronic device where an antenna is desired, such as a mobile phone, or a PDA. Referring to FIG. 2, the housing 10 includes a base 11, an antenna radiator 13, a decoration layer 15, and a number of conductive contacts 17. The antenna radiator 13 is a three dimensional antenna and is formed in the base 11 and is buried by the decoration layer 15. The conductive contacts 17 are embedded in the housing 10 by insert-molding. One end of each conductive contact 17 is electrically connected to the antenna radiator 13, and the other end is exposed from the housing 10 so that the electronic device can receive signals from the antenna radiator 13 or transmit signals by the antenna radiator 13.

Referring to FIG. 2, the base 11 may be made of a first moldable material. The first moldable material may comprise one or more plastics selected from a group consisting of polypropylene, polyamide, polycarbonate, polyethylene terephthalate, and polymethyl methacrylate.

The antenna radiator 13 includes a primary layer and a plating layer. The material of primary layer is a second moldable material, consisting essentially of thermal plastics mixed with organic fillers and laser activatable additives. The thermal plastics may be polyethylene terephthalate (PET) or polyimide (PI), for example. In this embodiment, the thermal plastics of the primary layer may have a weight percentage in a range from about 65% to about 75%. The organic fillers may be hydrated silica and/or hydrated silica derivatives and may have a percentage of about 22% to about 28% by weight in the material of primary layer. The laser activatable additives may be spinel-based non-conductive high oxides which contain metal crystal nuclei. The non-conductive high oxides can be a spinel containing copper. The spinel-based non-conductive high oxide may have a percentage of about 3% to about 7% by weight in the material of primary layer.

The primary layer can be laser activated because of the laser activatable additives. The primary layer predefines an activating region thereon. When the activating region is laser irradiated, the metal crystals contained in the laser activatable additives spread to cover the activated region, thus making the surface of the activated region electrically conductive so an electroplating process or other metallic coating depositing process can be applied to the activated region to form an antenna radiator 13. The antenna radiator 13 may be an electroplated coating formed on and bonded with the metal crystals of the activated region by electroplating after the activated region has been laser activated.

The primary layer is formed on the base 11. The plating layer is formed on the primary layer. In this exemplary embodiment, the plating layer includes a copper layer, a nickel layer and a gold layer in that order. The copper layer is plated on the primary layer. The nickel layer is a transition layer for increasing the bonding force between the copper layer and the gold layer. The gold layer is plated on the nickel layer. Since gold is highly resistant to oxidation, the gold layer protects the nickel layer and the copper layer.

The decoration layer 15 is formed on the base 11, and is buried on the antenna radiator 13. In this exemplary embodiment, the decoration layer is a Silicon Nitrogen (Si—N) layer. The Si—N layer is formed on the base 11 by physical vapor deposition (PVD).

A method for making the housing 10 of the embodiment includes the following steps:

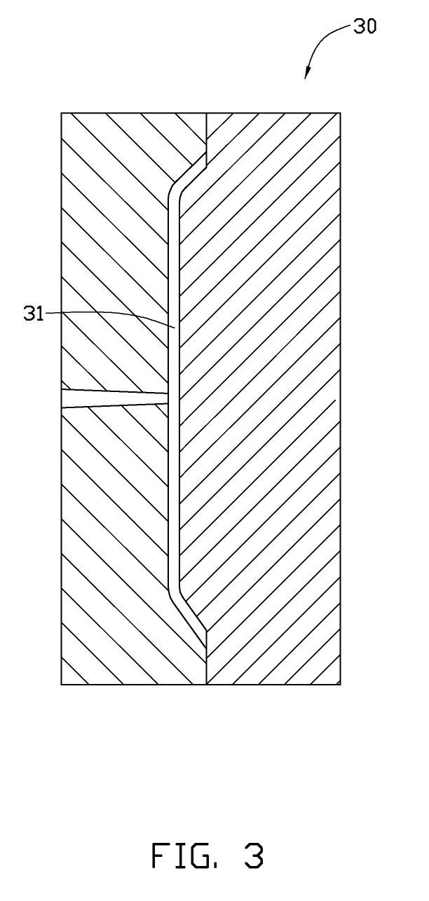

Referring to FIG. 3, an injection molding machine 30 is provided. The injection molding machine 30 is a multi-shot molding machine and includes a molding chamber 31.

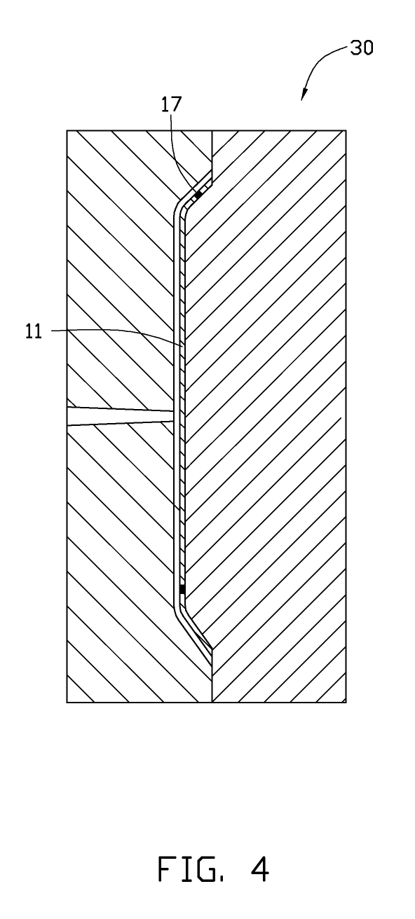

Referring to FIG. 4, the conductive contacts 17 are placed in the injection molding machine 30. Afterwards, non-plating molten plastic is fed into the molding chamber 31, and forms the base 11. The conductive contacts 17 are embedded in the base 11. The base 11 is made of a moldable plastic material, which may comprise one or more non-plating materials selected from a group consisting of polyethylene terephthalate (PET), and polyethylene methacrylate (PMMA).

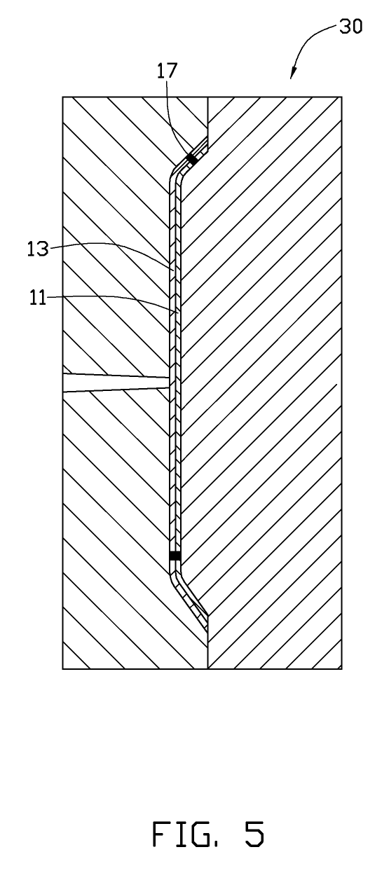

Referring to FIG. 5, the formation of the antenna radiator 13 is described in detail as follow. First, the thermal plastic is mixed with organic fillers and laser activatable additives according to the proportions described above to form a second moldable material. The second moldable material is injected into the molding chamber 31 for forming the primary layer on the base 11. Then, the primary layer is activated by laser device to form a laser activated area for preparing the plating. In this exemplary embodiment, a copper layer, a nickel layer, and a gold layer are formed on the activated area of the primary layer to form the plating layer. The nickel layer is plated on the copper layer. The nickel layer is a transition layer, and the gold layer is plated on the nickel layer.

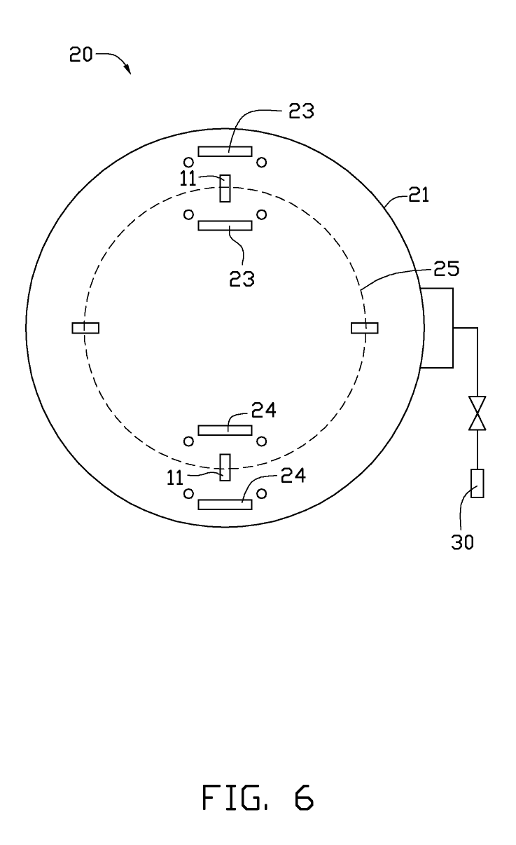

A vacuum sputtering process may be used to form the decoration layer 15 using a vacuum sputtering device 20. Referring to FIG. 6, the vacuum sputtering device 20 includes a vacuum chamber 21 and a vacuum pump 30 connected to the vacuum chamber 21. The vacuum pump 30 is used for evacuating the vacuum chamber 21. The vacuum chamber 21 has a pair of chromium targets 23, a pair of silicon targets 24 and a rotary rack (not shown) positioned therein. The rotary rack is rotated as it holds the substrate 11(circular path 25), and the substrate 11 revolves on its own axis while it is moved along the circular path 25.

Magnetron sputtering of the decoration layer 15 uses argon gas as sputtering gas. Argon gas has a flow rate of about 100 sccm to about 200 sccm. The temperature inside of the vacuum chamber during magnetron sputtering is at about 100° C. to about 150° C., the power of the silicon target is in a range of about 2 kw to about 8 kw, a negative bias voltage of about −50 V to about-100 V is applied to the substrate and the duty cycle is about 30% to about 50%. The vacuum sputtering of the base takes about 90 min to about 180 min, the Si—N layer has a thickness at a range of about 0.5 μm-about 1 μm.

The antenna radiator 13 is sandwiched between the base 11 and the decoration layer 15 so that the antenna radiator 13 is protected from being damaged. In addition, the antenna radiator 13 can be directly attached to the housing 10, thus, the working efficiency is increased.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A housing comprising:
a base made of a first moldable material;
an antenna radiator formed on the base, the antenna radiator including a primary layer and a plating layer, the primary layer made of a second moldable material;
a decoration layer formed on the plating layer of the antenna radiator; the antenna radiator sandwiched between the base and the decoration layer;
at least one conductive contact embedded in the base, one end of the at least one conductive contact electrically connected to the antenna radiator, and the other end of the at least one conductive contact exposed from the base.

2. The housing as claimed in claim 1, wherein the first moldable materials is selected from a group consisting of polypropylene, polyamide, polycarbonate, polyethylene terephthalate, and polymethyl methacrylate.

3. The housing as claimed in claim 1, wherein the second moldable materials is thermal plastics mixed with organic fillers and laser activatable additives.

4. The housing as claimed in claim 3, wherein the thermal plastic is polyethylene terephthalate or polyimide.

5. The housing as claimed in claim 4, wherein the thermal plastic is mixed by a weight percentage of 65-75%.

6. The housing as claimed in claim 3, wherein the organic fillers are hydrated silica and hydrated silica derivative.

7. The housing as claimed in claim 3, wherein the organic fillers have a percentage of 22-28% by weight in the second molding material.

8. The housing as claimed in claim 3, wherein the laser activatable additives are spinel-based non-conductive high oxides.

9. The housing as claimed in claim 9, wherein the spinel-based non-conductive high oxides have a percentage of 3-7% by weight in the second molding material.

10. The housing as claimed in claim 9, wherein the spinel-based non-conductive high oxide is a spinel containing copper.

11. The housing as claimed in claim 1, wherein the plating layer includes a copper layer, a nickel layer and an gold layer in that order.

12. The housing as claimed in claim 1, wherein the conductive contacts are embedded in the base.

13. The housing as claimed in claim 1, wherein the decoration layer is a non conductive Si—N layer.

14. A method for making a housing, comprising:
providing an injection molding machine defining a molding chamber;
placing at least one conductive contact into the molding chamber;
injecting a first moldable material into the molding chamber to form a base, the at least one conductive contact directly embedded in the base,
injecting a second moldable material on the base to form a primary layer, the second moldable material made of thermal plastic mixed with organic fillers and laser activatable additives;
plating a copper layer, a nickel layer and an gold layer in that order on the primary layer to form an antenna radiator;
forming a decoration layer, the decoration layer is a Si—N layer, forming Si—N layer by process of magnetron sputtering, the antenna radiator sandwiched between the decoration layer and the base.

15. The method for making a housing as claimed in claim 5, wherein magnetron sputtering the decoration layer uses argon gas as sputtering gas, argon gas has flow rates of 100 sccm to 200 sccm, the temperature of magnetron sputtering is at 100° C. to 150° C., the power of the silicon target is in a range of about 2 kw to about 8 kw, a negative bias voltage of −50 V to −100 V is applied to the substrate and the duty cycle is 30% to 50%, vacuum sputtering the base takes 90 min to 180 min, the Si—N layer has a thickness at a range of about 0.5 μm-1 μm.
